(19) United States
(12) Patent Application Publication
(10) Pub. No.: US 2021/0162469 A1
(43) Pub. Date: Jun. 3, 2021

(54) CLEANING RECIPE CREATION METHOD AND CLEANING METHOD

(71) Applicant: Tokyo Electron Limited, Tokyo (JP)

(72) Inventors: Daisuke SHIRASAWA, Miyagi (JP); Naoki SATO, Miyagi (JP)

(21) Appl. No.: 17/104,513

(22) Filed: Nov. 25, 2020

(30) Foreign Application Priority Data
Nov. 28, 2019 (JP) 2019-215698

(51) Int. Cl. B08B 7/04; B08B 5/00; B08B 7/00; B08B 9/08

(52) U.S. Cl. CPC B08B 7/04; B08B 9/08; B08B 7/005; B08B 5/00

(57) ABSTRACT

A cleaning recipe creation method includes: an etching process of, for each of predetermined combinations of temperatures and pressures, etching a metal compound stacked on a test substrate loaded into a chamber by using a cleaning gas supplied into the chamber; a measurement process of measuring an etching rate of the metal compound for each of the combinations of the temperatures and the pressures; and a creation process of, based on the etching rate of the metal compound measured for each of the combinations of the temperatures and the pressures, creating a cleaning recipe including the combinations of the temperatures and the pressures in which the etching rate is equal to or higher than a predetermined etching rate.

### CROSS-REFERENCE TO RELATED APPLICATION

This application is based upon and claims the benefit of priority from Japanese Patent Application No. 2019-215698, filed on Nov. 28, 2019, the entire contents of which are incorporated herein by reference.

### TECHNICAL FIELD

Various aspects and embodiments of the present disclosure relate to a cleaning recipe creation method and a cleaning method.

### BACKGROUND

In a semiconductor device manufacturing process, a processing gas supplied into a chamber is turned into plasma, and various processes such as film formation, etching and the like are performed on a substrate by radicals, ions and the like contained in the plasma. In the film formation and the etching, a reaction by-product (so-called deposit) is generated by the reaction between an element contained in the processing gas and an element contained in the substrate. The reaction by-product adheres to the inner wall of the chamber or the like. When the amount of the deposit adhering to the inner wall of the chamber or the like is large, the deposit separated from the inner wall of the chamber becomes particles and adheres to the substrate, which may cause deterioration of the characteristics of the processed substrate. Furthermore, when the amount of the deposit adhering to the inner wall of the chamber or the like increases, the resistance value of the inner wall of the chamber is changed, and the environment of the process such as film formation, etching or the like is also changed. This makes it difficult to perform a desired process on the substrate.

In order to avoid such a problem, there is known a technique of supplying a cleaning gas into a chamber, turning the supplied cleaning gas into plasma inside the chamber, and removing a deposit adhering to the inner wall of the chamber by the plasma, every time when etching is performed for a predetermined time.

### Prior Art Document

### Patent Document

Patent Document 1: Japanese Laid-Open Patent Publication No. 2006-173301

### SUMMARY

According to one embodiment of the present disclosure, there is provided a cleaning recipe creation method includes: an etching process of, for each of predetermined combinations of temperatures and pressures, etching a metal compound stacked on a test substrate loaded into a chamber by using a cleaning gas supplied into the chamber; a measurement process of measuring an etching rate of the metal compound for each of the combinations of the temperatures and the pressures; and a creation process of, based on the etching rate of the metal compound measured for each of the combinations of the temperatures and the pressures, creating a cleaning recipe including the combinations of the temperatures and the pressures in which the etching rate is equal to or higher than a predetermined etching rate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic sectional view showing an example of a plasma processing apparatus according to one embodiment of the present disclosure.

FIG. 2 is a view showing an example of a saturated vapor pressure curve of a metal compound.

FIG. 3 is a view showing an example of a post-etching film thickness of a metal or a metal compound at each temperature.

FIG. 4 is a view showing an example of a relationship between a pressure and an E/R.

FIG. 5 is a view showing an example of a relationship between a temperature and a pressure in a saturated vapor pressure curve.

FIG. 6 is a view for explaining an example of a process in which a metal compound is transformed into a volatile substance.

FIG. 7 is a view showing an example of a relationship between a pressure and an ion energy.

FIG. 8 is a flowchart showing an example of a cleaning recipe creation method.

FIG. 9 is a view showing an example of a measurement value table.

FIG. 10 is a view showing an example of a recipe table.

FIG. 11 is a flowchart showing an example of a cleaning method.

### DETAILED DESCRIPTION

Hereinafter, embodiments of a cleaning recipe creation method and a cleaning method will be described in detail with reference to the drawings. It should be noted that the following embodiments do not limit the cleaning recipe creation method and the cleaning method disclosed herein. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A material gas containing various metals may be used for film formation, and a film containing various metals may be an etching target even during etching. Therefore, various metals are also contained in the component of a deposit that adheres to the inner wall of a chamber due to the film formation or the etching. In that case, depending on the cleaning conditions, it may be difficult to remove the deposit adhering to the inner wall of the chamber by plasma. In such a case, the deposit adhering to the inner wall of the chamber is removed by opening the inside of the chamber to atmosphere, removing components constituting the chamber, and cleaning the components. As a result, it is necessary to evacuate the inside of the chamber again. Thus, it takes time to restart the process, and it is difficult to improve the throughput of the process.

Therefore, the present disclosure provides a technique capable of efficiently removing a deposit adhering to the inside of a chamber.

### [Configuration of Plasma Processing Apparatus 1]

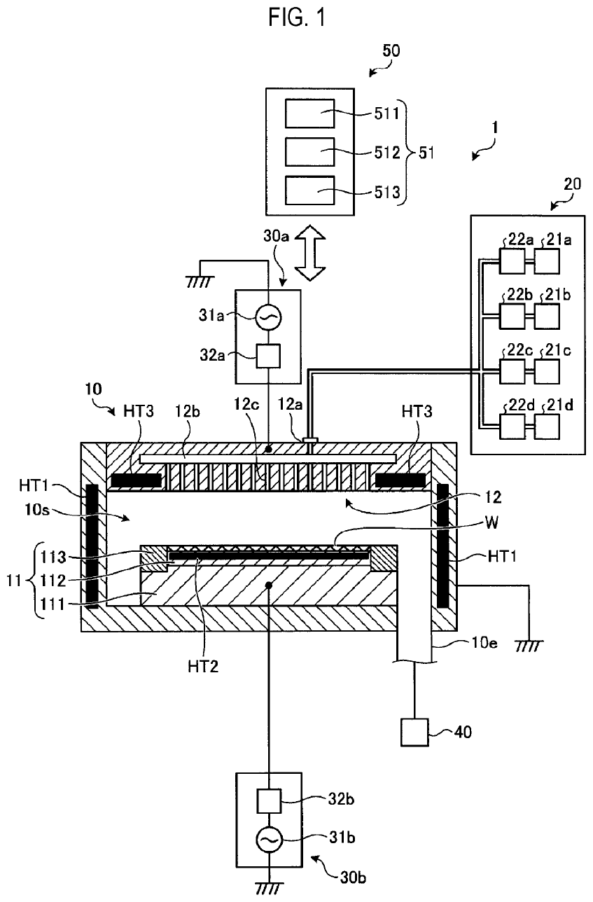

FIG. 1 is a schematic sectional view showing an example of a plasma processing apparatus 1 according to one embodiment of the present disclosure. In one embodiment, the plasma processing apparatus 1 includes a chamber 10, a gas supplier 20, a first RF (Radio Frequency) power supplier 30a, a second RF power supplier 30b, an exhaust system 40, and a controller 50.

In the present embodiment, the chamber 10 has a tubular shape with a processing space 10s formed therein. A heater HT1 for heating the side wall of the chamber 10 is embedded in the side wall of the chamber 10. The chamber 10 includes a support part 11 and an upper electrode showerhead assembly 12. The support part 11 is arranged in a lower region of the processing space 10s in the chamber 10. The upper electrode showerhead assembly 12 is located above the support part 11 and may function as a portion of a top plate of the chamber 10.

The support part 11 is configured to support a substrate W′ in the processing space 10s. In the present embodiment, the support part 11 includes a lower electrode 111, an electrostatic chuck 112, and an edge ring 113. The electrostatic chuck 112 is arranged on the lower electrode 111, and is configured to support the substrate W′ on the upper surface of the electrostatic chuck 112. A heater HT2 for heating the substrate W′ is embedded in the electrostatic chuck 112. The edge ring 113 is arranged so as to surround the substrate W′ on the upper surface of the peripheral edge portion of the lower electrode 111.

The upper electrode showerhead assembly 12 is configured to supply one or more processing gases from the gas supplier 20 into the processing space 10s. A heater HT3 for heating the upper electrode showerhead assembly 12 is embedded in the upper electrode showerhead assembly 12. In the present embodiment, the upper electrode showerhead assembly 12 includes a gas inlet 12a, a gas diffusion chamber 12b, and a plurality of gas outlets 12c. The gas supplier 20 and the gas diffusion chamber 12b are in fluid communication with each other through the gas inlet 12a. The gas diffusion chamber 12b and the processing space 10s are in fluid communication with each other through the plurality of gas outlets 12c. In the present embodiment, the upper electrode showerhead assembly 12 is configured to supply one or more processing gases from the gas inlet 12a into the processing space 10s via the gas diffusion chamber 12b and the plurality of gas outlets 12c.

The gas supplier 20 includes a plurality of gas sources 21a to 21d and a plurality of flow rate controllers 22a to 22d. The flow rate controllers 22a to 22d may include, for example, mass flow controllers or pressure-controlled flow rate controllers. Furthermore, the gas supplier 20 may include one or more flow rate modulation devices that modulate or pulse flow rates of the one or more processing gases.

In the present embodiment, the flow rate controller 22a controls the flow rate of the processing gas supplied from the gas source 21a, and supplies the flow-rate-controlled processing gas to the gas inlet 12a. The flow rate controller 22b controls the flow rate of a nitrogen trifluoride (NF₃) gas supplied from the gas source 21b, and supplies the flow-rate-controlled NF₃ gas to the gas inlet 12a. The flow rate controller 22c controls the flow rate of an oxygen (O₂) gas supplied from the gas source 21c, and supplies the flow-rate-controlled O₂ gas to the gas inlet 12a. The flow rate controller 22d controls the flow rate of an argon (Ar) gas supplied from the gas source 21d, and supplies the flow-rate-controlled Ar gas to the gas inlet 12a. The NF₃ gas is an example of a cleaning gas. The cleaning gas may be a chlorine (Cl₂) gas, a boron chloride (BCl₃) gas or the like as long as it contains chlorine or fluorine.

The first RF power supplier 30a is configured to supply a first RF power, for example one or more first RF signals, to the upper electrode showerhead assembly 12. Further, the second RF power supplier 30b is configured to supply a second RF power, for example, one or more second RF signals to the lower electrode 111. The spectra of the first RF signal and the second RF signal include a portion of the electromagnetic spectrum in the range of 3 Hz to 3,000 GHz. As for an electronic material process such as a semiconductor process or the like, the spectra of the first RF signal and the second RF signal used for plasma generation may be in the range of 100 kHz to 3 GHz, more specifically 200 kHz to 150 MHz.

The first RF power supplier 30a includes a first RF generator 31a and a first matching circuit 32a. The first RF power supplier 30a exemplified in the present embodiment is configured to supply the first RF signal from the first RF generator 31a to the upper electrode showerhead assembly 12 via the first matching circuit 32a. For example, the first RF signal may have a frequency in the range of 27 MHz to 100 MHz. The second RF power supplier 30b includes a second RF generator 31b and a second matching circuit 32b. The second RF power supplier 30b exemplified in the present embodiment is configured to supply the second RF signal from the second RF generator 31b to the lower electrode 111 via the second matching circuit 32b. For example, the second RF signal may have a frequency in the range of 400 kHz to 13.56 MHz.

A DC (Direct Current) pulse generator may be used instead of the second RF generator 31b. Although not shown, other embodiments are considered here. For example, in an alternative embodiment, an RF generator may be configured to supply a first RF signal to the lower electrode 111, another RF generator may be configured to supply a second RF signal to the lower electrode 111, and a further RF generator may be configured to supply a third RF signal to the upper electrode showerhead assembly 12. In addition, in another alternative embodiment, a DC voltage may be applied to the upper electrode showerhead assembly 12. Furthermore, in various embodiments, the amplitude of one or more RF signals (i.e., the first RF signal, the second RF signal, etc.) may be pulsed or modulated. The amplitude modulation may include pulsing the amplitude of the RF signal between an on-state and an off-state, or between different on-states. Moreover, the phase matching of the RF signals may be controlled, and the phase matching of the amplitude modulation of the plurality of RF signals may be synchronized or asynchronous.

The exhaust system 40 may be connected to, for example, an exhaust port 10e provided at the bottom of the chamber 10. The exhaust system 40 may include a pressure valve, and a vacuum pump such as a turbo molecular pump, a roughing pump or a combination thereof.

In the present embodiment, the controller 50 processes computer-executable instructions that cause the plasma processing apparatus 1 to perform the various processes described herein. The controller 50 may be configured to control each element of the plasma processing apparatus 1 to perform the various processes described herein. The controller 50 may include, for example, a computer 51. The computer 51 includes, for example, a processing unit (e.g., a CPU: Central Processing Unit) 511, a memory part 512, and a communication interface 513. The processing part 511 may be configured to perform various control operations based on programs and recipes stored in the memory part 512. The memory part 512 may include at least one non-transitory memory selected from a group of memories such as a RAM (Random Access Memory), a ROM (Read Only Memory), an HDD (Hard Disk Drive), an SSD (Solid State Drive), and the like. The communication interface 513 communicates with the plasma processing apparatus 1 via a communication line such as a LAN (Local Area Network) or the like.

In the plasma processing device 1 configured as above, when plasma processing such as film formation or etching is performed on the substrate W′ , a gate valve (not shown) is first opened, and a substrate W′ is placed on the electrostatic chuck 112 by a transfer device (not shown). Then, the processing part 511 controls the heater HT1 based on the process recipe stored in the memory part 512, and sets the temperature of the side wall of the chamber 10 to a desired temperature. Further, the processing part 511 controls the heater HT2 based on the process recipe stored in the memory part 512, and sets the temperature of the substrate W′ to a desired temperature. Moreover, the processing part 511 controls the heater HT3 based on the process recipe stored in the memory part 512, and sets the temperature of the upper electrode showerhead assembly 12 to a desired temperature. Then, the processing part 511 controls the exhaust system 40 to discharge the gas in the chamber 10, controls the flow rate controller 22a to supply the processing gas in the chamber 10 at a desired flow rate, and adjusts the internal pressure of the chamber 10. Then, the processing part 511 controls the first RF power supplier 30a to supply the first RF signal to the upper electrode showerhead assembly 12, and controls the second RF power supplier 30b to supply the second RF signal to the lower electrode 111. The processing gas supplied in the form of a shower from the upper electrode showerhead assembly 12 to the processing space 10s is turned into plasma by the first RF signal supplied from the first RF power supplier 30a to the upper electrode showerhead assembly 12. Then, ions and the like contained in the plasma are drawn into the substrate W′ by the second RF signal supplied from the second RF power supplier 30b to the lower electrode 111. As a result, the substrate W′ is subjected to plasma processing such as film formation or etching by the ions, the radicals and the like contained in the plasma.

Furthermore, at a predetermined timing, cleaning is performed to remove the deposit accumulated on the inner wall of the chamber 10. In the cleaning, the processing part 511 controls the heater HT1 based on the cleaning recipe stored in the memory part 512, and sets the temperature of the side wall of the chamber 10 to a desired temperature. Further, the processing part 511 controls the heater HT2 based on the cleaning recipe stored in the memory part 512, and sets the temperature of the upper surface of the electrostatic chuck 112 to a desired temperature. Moreover, the processing part 511 controls the heater HT3 based on the cleaning recipe stored in the memory part 512, and sets the temperature of the upper electrode showerhead assembly 12 to a desired temperature. As a result, the deposit deposited on the inner wall of the chamber 10 is heated to a desired temperature. Then, the processing part 511 controls the exhaust system 40 to discharge the gas in the chamber 10. Further, the processing part 511 controls the flow rate controller 22a to supply a mixed gas including a desired flow rate of NF₃ gas, a desired flow rate of O₂ gas and a desired flow rate of Ar gas into the chamber 10, and adjusts the internal pressure of the chamber 10. Then, the processing part 511 controls the first RF power supplier 30a to supply the first RF signal to the upper electrode showerhead assembly 12, and turns the mixed gas into plasma inside the processing space 10s. The second RF signal may be supplied to the lower electrode 111 from the second RF power supplier 30b. The deposit deposited on the inner wall of the chamber 10 is removed by the ions, the radicals and the like contained in the plasma.

### [About Deposit Containing Metal Compound]

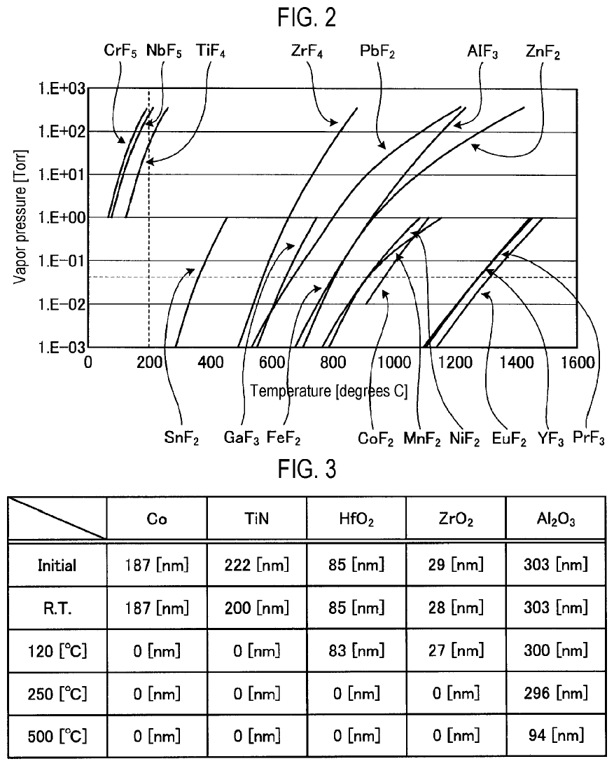

In this regard, the deposit of the metal compound is deposited on the inner wall of the chamber 10 in a solid state. Depending on the conditions such as the internal pressure of the chamber 10 and the temperature of the inner wall of the chamber 10, the deposit of the metal compound may be changed to a gaseous state and may be discharged together with the gas supplied into the chamber 10. The state of the metal compound is represented by, for example, a saturated vapor pressure curve as shown in FIG. 2. FIG. 2 is a view showing an example of saturated vapor pressure curves of metal compounds. The state of each metal compound is a gas on the right side of the saturated vapor pressure curve and a solid (or liquid) on the left side of the saturated vapor pressure curve. In FIG. 2, the saturated vapor pressure curves of metal fluorides are shown.

As illustrated in FIG. 2, the position of the saturated vapor pressure curve indicating the boundary between the gas and the solid (or liquid) differs depending on the material of the metal compound. For example, in CrF₅, NbF₅ and TiF₄, the saturated vapor pressure curve is located in a region where the vapor pressure is relatively high and the temperature is relatively low. In these metal compounds, the temperature at which the metal compounds are in a gaseous state is less than 200 degrees C. at a vapor pressure of 5 mTorr. Therefore, when the deposit deposited in the chamber 10 is composed of these metal compounds, the deposit can be converted into a gaseous state without lowering the pressure and raising the temperature so much, and can be easily discharged together with the gas supplied into the chamber 10.

On the other hand, for example, in ZrF₄, CoF₂, SnF₂, ZnF₂ and the like, the saturated vapor pressure curve is located in a region where the vapor pressure is relatively low and the temperature is relatively high. In these metal compounds, the temperature at which the metal compounds are in a gaseous state is 200 degrees C. or higher at a vapor pressure of 5 mTorr. Therefore, when the deposit deposited in the chamber 10 is composed of these metal compounds, it is difficult to convert the deposit into a gaseous state unless the pressure is lowered to some extent and the temperature is raised to some extent. For that reason, when the deposit deposited in the chamber 10 is composed of these metal compounds, it is difficult to discharge the deposit together with the gas supplied into the chamber 10.

Thus, the deposit of a metal compound containing zirconium, cobalt, tin or zinc is difficult to remove by cleaning. In addition, it is difficult to remove the deposit of a metal compound containing hafnium, indium or the like by cleaning. In the present embodiment, particularly, the deposit of a metal compound containing at least one of hafnium, zirconium, cobalt, indium, tin and zinc can be efficiently removed.

[Deposit Etching Rate with Respect to Temperature]

FIG. 3 is a view showing an example of post-etching film thicknesses of metals or metal compounds for each temperature. In the experiments, the thicknesses of the metals or the metal compounds were measured when a test substrate W′ obtained by stacking a metal or a metal compound exemplified in FIG. 3 on a silicon substrate is etched under the following conditions.

Pressure: 45 mTorr

First RF: 500 W

Second RF: 0 W

NF₃ gas: 100 sccm

O₂ gas: 20 sccm

Ar gas: 200 sccm

Processing time: 1 minute

In a test substrate W′ on which CO is stacked, the CO film was hardly etched when the temperature of the test substrate W′ is room temperature. However, when the temperature of the test substrate W′ is 120 degrees C. or higher, the CO film of 187 nm was entirely etched. That is, in the test substrate W′ in which CO is stacked, when the temperature of the test substrate W′ is 120 degrees C. or higher, an etching rate (E/R) was 187 nm/min or higher.

In the test substrate W′ on which TiN is stacked, the TiN film was etched only about 22 nm when the temperature of the test substrate W′ is room temperature. However, when the temperature of the test substrate W′ is 120 degrees C. or higher, the TiN film of 222 nm was entirely etched. That is, in the test substrate W′ on which TiN is stacked, when the temperature of the test substrate W′ is 120 degrees C. or higher, the E/R was 222 nm/min or higher.

In the test substrate W′ on which HfO₂ is stacked, the HfO₂ film was hardly etched when the temperature of the test substrate W′ is room temperature. When the temperature of the test substrate W′ is 120 degrees C., the HfO₂ film was etched only about 2 nm. However, when the temperature of the test substrate W′ is 250 degrees C. or higher, the HfO₂ film of 85 nm was entirely etched. That is, in the test substrate W′ on which HfO₂ is stacked, when the temperature of the test substrate W′ is 250 degrees C. or higher, the E/R was 85 nm/min or higher.

In the test substrate W′ on which ZrO₂ is stacked, the ZrO₂ film was etched only about 1 nm when the temperature of the test substrate W′ is room temperature. Even when the temperature of the test substrate W′ is 120 degrees C., the ZrO₂ film was etched only about 2 nm. However, when the temperature of the test substrate W′ is 250 degrees C. or higher, the ZrO₂ film of 29 nm was entirely etched. That is, in the test substrate W′ on which ZrO₂ is stacked, when the temperature of the test substrate W′ is 250 degrees C. or higher, the E/R was 29 nm/min or higher.

In the test substrate W′ on which Al₂O₃ is stacked, when the temperature of the test substrate W′ is room temperature, the Al₂O₃ film was hardly etched. Even when the temperature of the test substrate W′ is 120 degrees C., the Al₂O₃ film was etched only about 3 nm. Even when the temperature of the test substrate W′ is 250 degrees C., the Al₂O₃ film was only about 7 nm. However, when the temperature of the test substrate W′ is 500 degrees C., the Al₂O₃ film of 209 nm was etched. That is, in the test substrate W′ on which Al₂O₃ is stacked, when the temperature of the test substrate W′ is 500 degrees C. or higher, the E/R was 209 nm/min or higher.

As described above, even if the deposit is composed of a metal compound that is hardly etched at the room temperature, the etching of the deposit proceeds by raising the temperature. Therefore, in order to efficiently remove the deposit, it is considered effective to raise the temperature of the deposit by heating the inner wall of the chamber 10 on which the deposit is deposited or the deposit itself.

### [Relationship Between Pressure and E/R]

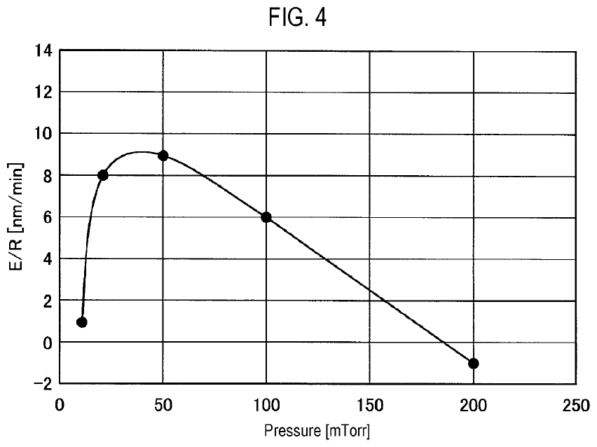

FIG. 4 is a view showing an example of the relationship between a pressure and an E/R. In the experiment shown in FIG. 4, the etching rate (E/R) when the test substrate W′ obtained by stacking ZrO2 on a silicon substrate is etched under the following conditions was measured.

First RF: 300 W

Second RF: 0 W

BCl₃ gas: 100 sccm

Ar gas: 200 sccm

Temperature of test substrate W′: 270 degrees C.

Processing time: 1 minute

Referring to FIG. 4, there is a maximum point of the E/R with respect to a change in pressure. In a region where the pressure is lower than that at the maximum point of the E/R, the higher the pressure, the larger the E/R. On the other hand, in a region where the pressure is higher than that at the maximum point of the E/R, the higher the pressure, the smaller the E/R. A mechanism by which such an E/R change occurs in response to a pressure change will be considered below.

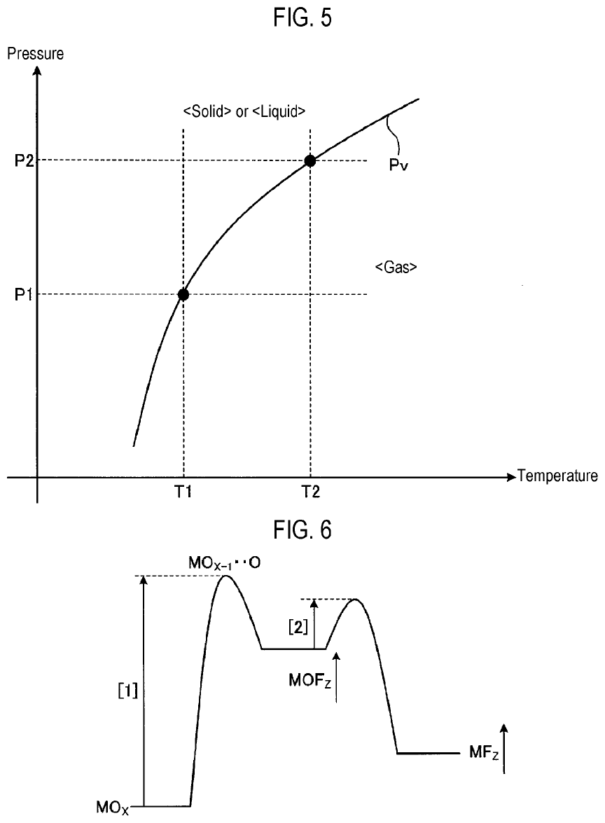

FIG. 5 is a view showing an example of a relationship between a temperature T and a pressure P on a saturated vapor pressure curve Pv. When the saturated vapor pressure curve of the metal compound to be cleaned is, for example, the saturated vapor pressure curve Pv shown in FIG. 5, if the internal pressure P of the chamber 10 is a pressure P1, the metal compound can be vaporized by increasing the temperature T of the metal compound to a temperature T1. On the other hand, if the internal pressure P of the chamber 10 is a pressure P2 higher than the pressure P1, the metal compound cannot be vaporized unless the temperature T of the metal compound is increased to a temperature T2 or higher, which is higher than the temperature T1. That is, it seems that the metal compound can be vaporized and removed by lowering the internal pressure P of the chamber 10 and increasing the temperature T of the metal compound.

FIG. 6 is a view for explaining an example of a process of changing a metal compound into a volatile substance. In FIG. 6, the following reaction formula (1) is premised.

MOₓ+nF→Mf₂↑+½XO₂↑ (1)

In the above reaction formula (1), M denotes a metal atom, O denotes an oxygen atom, and F denotes an etchant atom.

In FIG. 6, the metal compound MO_{X} to which the energy exceeding activation energy [1] and energy exceeding [2] is applied is subjected to desorption of oxygen atoms and changed to a volatile substance MF_{Z} via an intermediate product MOF_{Z}. Therefore, in order to change the metal compound MO_{X} into the volatile substance MF_{Z}, it is necessary to apply the energy exceeding activation energy [1] and activation energy [2] to the metal compound MO_{X}. The magnitude of activation energy [1] and activation energy [2] mainly depends on four factors, i.e., the type of the metal compound MO_{X}, the type of the etchant F, the internal pressure P of the chamber 10 and the temperature T of the metal compound MO_{X}.

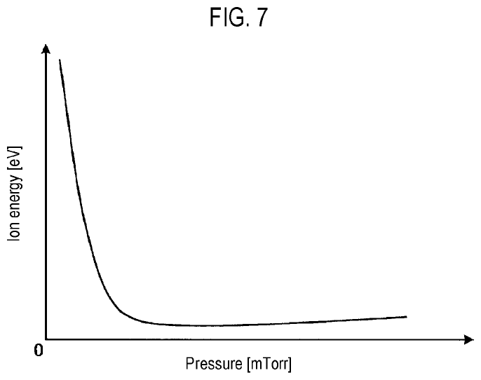

The results shown in FIG. 7 were obtained by measuring the relationship between the internal pressure P of the chamber 10 and the ion energy incident on the substrate W inside the chamber 10. FIG. 7 is a view showing an example of a relationship between the pressure and the ion energy. For example, as shown in FIG. 7, when the pressure P is low, the ion energy in the chamber 10 tends to be large, and when the pressure P is high, the ion energy in the chamber 10 tends to be small.

When the ion energy is large, the ion energy is likely to exceed the activation energy [1]and the activation energy [2], whereby the reaction represented by the above formula (1) is promoted. On the other hand, when the ion energy is small, the ion energy is difficult to exceed the activation energy [1] and the activation energy [2], whereby the reaction represented by the above formula (1) becomes difficult to proceed. That is, it is considered that when the pressure P is low, the reaction represented by the above formula (1) is promoted, and when the pressure P is high, the reaction represented by the above formula (1) is difficult to proceed.

A reaction rate r in the process of changing the metal compound into the volatile substance is represented as follows, for example.

r=k[,O_{X}]^{x}[nF]^{y} (2)

A constant k in the above formula (2) is represented as follows by the Eyring equation.

$$k = κ \frac{{k}_{B} T}{h} exp ( - \frac{Δ {G}^{‡}}{RT} ) \qquad ( 3 )$$

In the above formula (3), k denotes the transmission coefficient, k_{B} denotes the Boltzmann constant, h denotes Planck's constant, R denotes the gas constant, and ΔG^{‡} denotes the activation energy.

Referring to the above formula (2), it can be seen that the higher the concentration of etchant F, the higher the reaction rate r, and the lower the concentration of etchant F, the lower the reaction rate r. That is, when the internal pressure P of the chamber 10 becomes low, the concentration of the etchant in the chamber 10 becomes low. Thus, the reaction rate r becomes low, and the reaction represented by the above reaction formula (1) becomes difficult to proceed. Therefore, if the internal pressure P of the chamber 10 is too low, the E/R becomes smaller on the contrary.

In summary, in the pressure range larger than a certain level, the reaction represented by the above reaction formula (1) is controlled by the magnitude of the ion energy. As the pressure P grows lower, the reaction represented by the reaction formula (1) is promoted and the E/R becomes large. On the other hand, in the pressure range smaller than the certain level, the reaction represented by the above reaction formula (1) is controlled by the concentration of the etchant. As the pressure P grows higher, the reaction rate r becomes large, the reaction represented by the reaction formula (1) is promoted and the E/R becomes large. Thus, as shown in FIG. 4, it is considered that the maximum point of the E/R with respect to the change in pressure appears.

The pressure at the maximum point of the E/R depends on the combination of the type of the metal compound, the type of the etchant and the temperature T of the metal compound. Further, in FIG. 4, the E/R of 1 nm/min or less may possibly be a measurement error. Therefore, the pressure range in which the E/R becomes a predetermined value (e.g., 2 nm/min) or more may be adopted as the pressure range in which the metal compound is surely etched. Such a pressure range also depends on the combination of the type of the metal compound, the type of the etchant and the temperature T of the metal compound. Therefore, as for the combination of the type of the metal compound, the type of the etchant and the temperature T of the metal compound, it is preferable that the pressure included in the pressure range in which the E/R becomes a predetermined value or more is set in the cleaning recipe. Moreover, as for the combination of the type of the metal compound, the type of the etchant and the temperature T of the metal compound, it is more preferable that the pressure at which the E/R becomes a maximum value is set in the cleaning recipe.

### [Cleaning Recipe Creation Method]

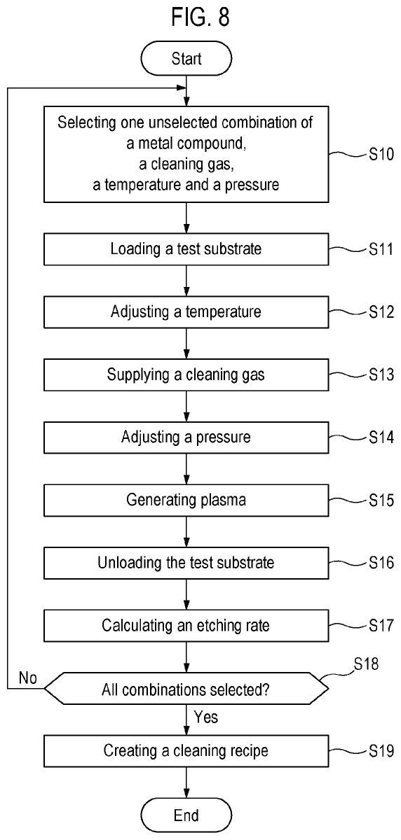

FIG. 8 is a flowchart showing an example of a cleaning recipe creation method. A procedure shown in FIG. 8 is performed at a predetermined timing. The predetermined timing is, for example, after replacing the components of the plasma processing apparatus 1, after processing a predetermined number of substrates W by the plasma processing apparatus 1, after a predetermined time has elapsed from the start of the operation of the plasma processing apparatus 1, or the like.

First, one unselected combination is selected from the predetermined combinations of the type of the metal compound to become a deposit, the type of the cleaning gas, the temperature of the metal compound and the internal pressure of the chamber 10 (S10). The type of the metal compound to become a deposit and the type of the cleaning gas may be predetermined.

Subsequently, the test substrate W′ on which the metal compound contained in the combination selected in step S10 is stacked is loaded into the chamber 10 and placed on the electrostatic chuck 112 (S11).

Subsequently, by controlling the heater HT2, the temperature of the test substrate W′ placed on the electrostatic chuck 112 is adjusted so as to become the temperature included in the combination selected in step S10 (S12). The heaters HT1 and HT3 may also be controlled together.

Subsequently, the cleaning gas of the type included in the combination selected in step S10 is supplied from the gas supplier 20 into the chamber 10 (S13).

Subsequently, the internal pressure of the chamber 10 is adjusted by controlling the flow rate controllers 22b to 22d and the exhaust system 40 so that the internal pressure of the chamber 10 becomes the pressure included in the combination selected in step S10 (S14).

Subsequently, by supplying the first RF signal from the first RF power supplier 30a to the upper electrode showerhead assembly 12, the cleaning gas is turned into plasma inside the chamber 10, whereby plasma is generated inside the chamber 10 (S15). The film of the metal compound is etched by ions, radicals and the like contained in the plasma. Step S15 is an example of an etching process. In step S15, the second RF signal may be supplied from the second RF power supplier 30b to the lower electrode 111.

Subsequently, after a predetermined time (e.g., 1 minute), the test substrate W′ is unloaded from the chamber 10 (S16).

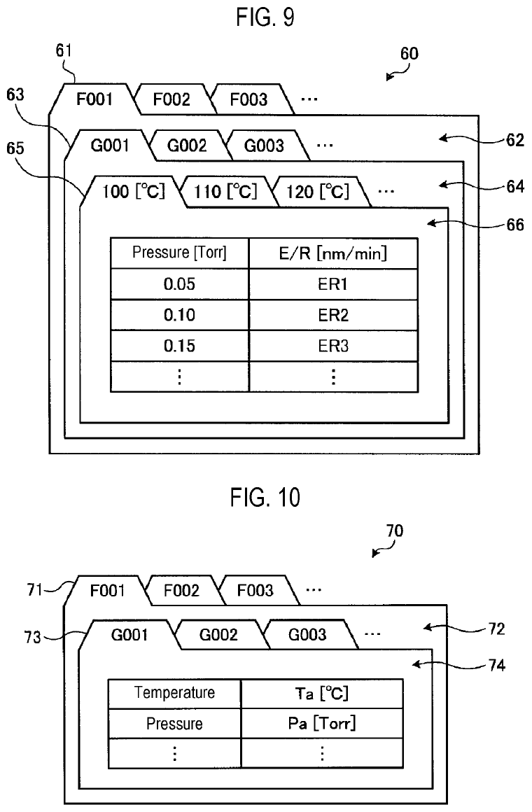

Thereafter, the film thickness of the metal compound on the test substrate W′ is measured by a film thickness measurement instrument such as an Esoprimeter or the like. An E/R is calculated from the difference between the film thickness of the metal compound before etching and the film thickness of the metal compound after etching (S17). Step S17 is an example of a measurement process. Then, the calculated E/R for each combination of the type of the metal compound, the type of the cleaning gas, the temperature of the metal compound and the internal pressure of the chamber 10 is stored in a measurement value table 60 shown in FIG. 9, for example. The measurement value table 60 is stored in, for example, the memory part 512 of the computer 51, and is managed and edited by the processing part 511.

FIG. 9 is a view showing an example of the measurement value table 60. In the measurement value table 60, a gas type table 62 is stored in association with a film type ID 61 that identifies each type of metal compound. The gas type table 62 stores a temperature table 64 in association with a gas type ID 63 that identifies each type of cleaning gas. In the temperature table 64, an E/R table 66 is stored in association with each predetermined temperature 65. The E/R table 66 stores a measurement value of E/R for each pressure.

Subsequently, it is determined whether or not all the combinations have been selected from the predetermined combinations of the type of the metal compound, the type of the cleaning gas, the temperature of the metal compound and the internal pressure of the chamber 10 (S18). If there is an unselected combination (S18: No), the process shown in step S10 is executed again.

On the other hand, when all combinations are selected (S18: Yes), a temperature range and a pressure range in which the E/R becomes a predetermined E/R (e.g., 2 nm/min) or more are specified for each combination of the metal compound and the cleaning gas. Then, for each combination of the metal compound and the cleaning gas, a cleaning recipe including the temperature and the pressure included in the specified ranges is created (S19). Step S19 is an example of a creation process. The recipe created for each combination of the metal compound and the cleaning gas is stored in, for example, a recipe table 70 shown in FIG. 10 and stored in the memory part 512 of the computer 51. Then, the cleaning recipe creation method shown in FIG. 8 is completed.

FIG. 10 is a view showing an example of the recipe table 70. In the recipe table 70, a gas type table 72 is stored in association with a film type ID 71 that identifies each type of metal compound. In the gas type table 72, a cleaning recipe 74 is stored in association with a gas type ID 73 that identifies each type of cleaning gas. The cleaning recipe 74 stores various cleaning settings, including the temperature and pressure specified by the process shown in FIG. 8.

### [Cleaning Method]

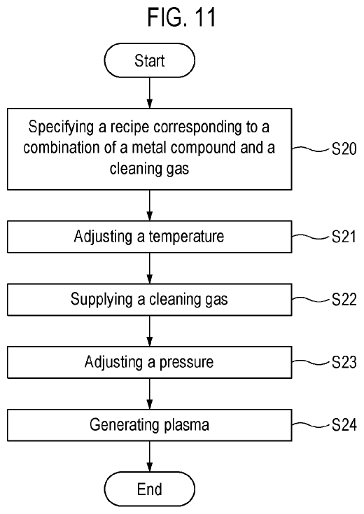

FIG. 11 is a flowchart showing an example of a cleaning method. The process shown in FIG. 11 is realized, for example, by the processing part 511 that executes a program or the like stored in the memory part 512 and controls each part of the plasma processing apparatus 1. Further, the cleaning method shown in FIG. 11 is performed at a predetermined timing. The predetermined timing is, for example, after a predetermined number of substrates W have been processed by the plasma processing apparatus 1, or after a predetermined time has elapsed from the execution of the previous cleaning.

First, the processing part 511 refers to the recipe table 70 stored in the memory part 512 and specifies the cleaning recipe 74 corresponding to the combination of the metal compound and the cleaning gas specified by the user of the plasma processing apparatus 1 (S20). The combination of the metal compound and the cleaning gas is specified by the user via an input interface such as a keyboard or the like (not shown).

Subsequently, the processing part 511 controls the heaters HT1 to HT3 to thereby adjust the temperature of the inner wall of the chamber 10 so that the temperature of the inner wall of the chamber 10 becomes the temperature described in the recipe specified in step S20 (S21). Step S21 is an example of a temperature adjustment process.

Subsequently, the processing part 511 supplies the cleaning gas specified by the user into the chamber 10 by controlling the flow rate controllers 22b to 22d (S22). Step S22 is an example of a supply process.

Next, the processing part 511 controls the flow rate controllers 22b to 22d and the exhaust system 40 to adjust the internal pressure of the chamber 10 so that the internal pressure of the chamber 10 becomes the pressure described in the recipe specified in step S20 (S23). Step S23 is an example of a pressure adjustment process.

Subsequently, the processing part 511 supplies the first RF signal to the upper electrode showerhead assembly 12 by controlling the first RF power supplier 30a. As a result, the cleaning gas is turned into plasma inside the chamber 10, whereby plasma is generated inside the chamber 10 (S24). Then, the film of the metal compound stacked on the inner wall of the chamber 10 is etched and removed by ions, radicals and the like contained in the plasma. Step S24 is an example of a removal process. In step S24, the second RF signal may be supplied from the second RF power supplier 30b to the lower electrode 111.

Then, after the plasma is generated inside the chamber 10 for a predetermined time (e.g., several minutes), the supply of the first RF signal and the supply of the cleaning gas are stopped. The cleaning method shown in this flowchart is completed.

One embodiment has been described above. As described above, the cleaning recipe creation method according to the present embodiment includes the etching process, the measurement process and the creation process. In the etching process, for each of predetermined combinations of temperatures and pressures, the metal compound stacked on the test substrate W′ loaded into the chamber 10 is etched by using the cleaning gas supplied into the chamber 10. In the measurement process, the etching rate of the metal compound is measured for each combination of the temperature and the pressure. In the creation process, the cleaning recipe including the combination of the temperature and the pressure in which the etching rate is equal to or higher than a predetermined etching rate is created based on the etching rate of the metal compound measured for each combination of the temperature and the pressure. By performing the cleaning through the use of the recipe created by such a method, the deposit adhering to the inside of the chamber can be efficiently removed.

Furthermore, in the above-described embodiment, the etching process and the measurement process are performed for each of the combinations of the plurality of predetermined cleaning gases and the plurality of metal compounds. Moreover, in the creation process, the recipe including the combination of the cleaning gas, the metal compound, the temperature and the pressure in which the etching rate is equal to or higher than a predetermined etching rate is created. Thus, as for any combination of the cleaning gas and the metal compound, it is possible to create a cleaning recipe capable of efficiently removing the deposit adhering to the inside of the chamber.

Furthermore, in the above-described embodiment, at the vapor pressure of 5 mTorr, the metal compound is in a gaseous state at the temperature of 200 degrees C. or higher. By performing the cleaning through the use of the recipe created by such a method, it is possible to remove the deposit containing the metal compound that is in a gaseous state at the vapor pressure of 5 mTorr and at the temperature of 200 degrees C. or higher.

Furthermore, in the above-described embodiment, the metal compound is a compound containing at least one selected from the group consisting of hafnium, zirconium, cobalt, indium, tin and zinc. By performing the cleaning through the use of the recipe created by such a method, it is possible to remove the deposit containing the metal compound including hafnium, zirconium, cobalt, indium, tin, zinc and the like.

Furthermore, in the above-described embodiment, the cleaning gas is a gas containing chlorine or fluorine. The cleaning gas is, for example, a chlorine gas, a boron chloride gas, or a nitrogen trifluoride gas. As a result, it is possible to efficiently remove the deposit adhering to the inside of the chamber.

Furthermore, the cleaning method according to the present embodiment includes the etching process, the measurement process, the creation process, the temperature adjustment process, the supply process, the pressure adjustment process and the removal process. In the etching process, for each of predetermined combinations of temperatures and pressures, the metal compound stacked on the test substrate W′ loaded into the chamber 10 is etched by using the cleaning gas supplied into the chamber 10. In the measurement process, the etching rate of the metal compound is measured for each combination of the temperature and the pressure. In the creation process, the cleaning recipe including the combination of the temperature and the pressure in which the etching rate is equal to or higher than a predetermined etching rate is created based on the etching rate of the metal compound measured for each combination of the temperature and the pressure. In the temperature adjustment process, the temperature of the inner wall of the chamber 10 is adjusted so as to become the temperature described in the cleaning recipe created by the above method. In the supply process, the cleaning gas is supplied into the chamber 10. In the pressure adjustment process, the internal pressure of the chamber 10 is adjusted so as to become the pressure described in the cleaning recipe created by the above method. In the removal process, the metal compound adhering to the inner wall of the chamber 10 is removed by turning the cleaning gas into plasma inside the chamber 10. Therefore, it is possible to efficiently remove the deposit adhering to the inside of the chamber.

### [Others]

The technique disclosed herein is not limited to the above-described embodiments, and many modifications may be made within the scope of the gist thereof.

For example, the above-described embodiment is applicable to compounds other than the metal compound including hafnium, zirconium, cobalt, indium, tin, zinc, and the like, wherein the temperature at which the metal compound is in a gaseous state is 200 degrees C. or higher at a vapor pressure of 5 mTorr. Specifically, the above-described embodiment is similarly applicable to a metal compound including chromium, niobium, titanium, and the like, wherein the temperature at which the metal compound is in a gaseous state is 200 degrees C. or less at a vapor pressure of 5 mTorr. That is, even in these metal compounds, by creating a cleaning recipe in the similar manner and performing the cleaning through the use of the created recipe, the deposit of the metal compounds adhering to the inside of the chamber can be efficiently removed.

Further, in the above-described embodiment, the temperature of the inner wall of the chamber 10 is adjusted by the heaters HT1 to HT3. However, the technique disclosed herein is not limited thereto. For example, the temperature of the deposit stacked on the surface of the inner wall of the chamber 10 may be adjusted by irradiating the inner wall of the chamber 10 with infrared rays by a halogen lamp or the like. As a result, the depot itself stacked on the surface of the inner wall of the chamber 10 can be heated. Therefore, it is possible to more accurately adjust the temperature of the deposit. Since the members constituting the inner wall of the chamber 10 have a large heat capacity, a large amount of electric power is required to raise the temperature of the inner wall of the chamber 10 to a predetermined temperature. On the other hand, by irradiating the surface of the inner wall of the chamber 10 with infrared rays, the temperature of the deposit stacked on the surface of the inner wall can be raised more quickly with less electric power.

Furthermore, in the above-described embodiment, the plasma processing apparatus 1 that performs the processing through the use of the capacitively coupled plasma (CCP) has been described as an example of the plasma source. However, the plasma source is not limited thereto. Examples of the plasma source other than the capacitively coupled plasma include inductively coupled plasma (ICP), microwave-excited surface wave plasma (SWP), electron cyclotron resonance plasma (ECP), and helicon-wave-excited plasma (HWP).

According to the present disclosure in some embodiments, it is possible to efficiently remove a deposit adhering to the inside of the chamber.

It should be noted that the embodiment disclosed herein is an example in all respects and is not restrictive. Indeed, the above-described embodiment may be implemented in a variety of forms. Furthermore, the above-described embodiment may be omitted, replaced or changed in various forms without departing from the scope of the appended claims and the spirit thereof.

What is claimed is:

1. A cleaning recipe creation method, the method comprising:
(a) etching a metal compound stacked on a test substrate loaded into a chamber by using a cleaning gas supplied into the chamber, for each of predetermined combinations of temperatures and pressures;
(b) measuring an etching rate of the metal compound for each of the combinations of the temperatures and the pressures; and
(c) creating a cleaning recipe including the combinations of the temperatures and the pressures in which the etching rate is equal to or higher than a predetermined etching rate, based on the etching rate of the metal compound measured for each of the combinations of the temperatures and the pressures.

2. The cleaning recipe creation method of claim 1, wherein (a) and (b) are performed for each of predetermined combinations of cleaning gases and metal compounds, and
a recipe is created in the creation process that includes a combination of the cleaning gas, the metal compound, the temperature and the pressure in which the etching rate is equal to or higher than the predetermined etching rate.

3. The cleaning recipe creation method of claim 2, wherein the metal compound is in a gaseous state at a vapor pressure of 5 mTorr and at a temperature of 200 degrees C. or higher.

4. The cleaning recipe creation method of claim 1, wherein the metal compound is a compound including at least one selected from a group consisting of hafnium, zirconium, cobalt, indium, tin and zinc.

5. The cleaning recipe creation method of claim 1, wherein the cleaning gas is a gas containing chlorine or fluorine.

6. The cleaning recipe creation method of claim 1, wherein the cleaning gas is a chlorine gas, a boron chloride gas or a nitrogen trifluoride gas.

7. A cleaning method, comprising:
(a) etching a metal compound stacked on a test substrate loaded into a chamber by using a cleaning gas supplied into the chamber for each of predetermined combinations of temperatures and pressures;
(b) measuring an etching rate of the metal compound for each of the combinations of the temperatures and the pressures;
(c) creating a cleaning recipe including the combinations of the temperatures and the pressures in which the etching rate is equal to or higher than a predetermined etching rate based on the etching rate of the metal compound measured for each of the combinations of the temperatures and the pressures;
(d) adjusting a temperature of an inner wall of the chamber so as to become a temperature described in the cleaning recipe;
(e) supplying the cleaning gas into the chamber;
(f) adjusting an internal pressure of the chamber so as to become a pressure described in the cleaning recipe; and
(g) removing the metal compound adhering to the inner wall of the chamber by turning the cleaning gas into plasma inside the chamber.

8. The cleaning method of claim 7, wherein in (d), the temperature of the metal compound is adjusted by irradiating the inner wall of the chamber or the metal compound adhering to the inner wall of the chamber with infrared rays.

9. The cleaning method of claim 7, wherein the metal compound is a compound including at least one selected from a group consisting of hafnium, zirconium, cobalt, indium, tin and zinc.

10. The cleaning method of claim 7, wherein the cleaning gas is a gas containing chlorine or fluorine.

11. The cleaning method of claim 7, wherein the cleaning gas is a chlorine gas, a boron chloride gas or a nitrogen trifluoride gas.

12. The cleaning method of claim 7, wherein the metal compound is in a gaseous state at a vapor pressure of 5 mTorr and at a temperature of 200 degrees C. or higher.
